(19) United States
(12) Patent Application Publication
(10) Pub. No.: US 2025/0040304 A1
(43) Pub. Date: Jan. 30, 2025

(54) NITRIDE SEMICONDUCTOR LIGHT-EMITTING ELEMENT

(71) Applicant: NIKKISO CO., LTD., Tokyo (JP)

(72) Inventors: Kazufumi TAKAO, Ishikawa (JP); Yusuke MATSUKURA, Ishikawa (JP); Cyril PERNOT, Ishikawa (JP)

(73) Assignee: NIKKISO CO., LTD., Tokyo (JP)

(21) Appl. No.: 18/779,183

(22) Filed: Jul. 22, 2024

(30) Foreign Application Priority Data
Jul. 25, 2023 (JP) 2023-120526

(51) Int. Cl. H01L 33/32; H01L 33/14; H01L 33/24

(52) U.S. Cl. CPC H01L 33/32; H01L 33/145; H01L 33/24

(57) ABSTRACT

A nitride semiconductor light-emitting element includes an n-type semiconductor layer, an active layer being formed on the n-type semiconductor layer and emitting ultraviolet light, an electron blocking layer formed on the active layer, and a p-type semiconductor layer formed on the electron blocking layer. A plurality of pits are formed at least in the active layer. A ratio R=D2/D1, which is a ratio of a second density D2 to a first density D1, is less than 30%, where the first density D1 is a density of the pits on an upper surface of the active layer and the second density D2 is a density of the pits on an upper surface of the electron blocking layer.

### CROSS-REFERENCE TO RELATED APPLICATIONS

The present application is based on Japanese patent application No. 2023-120526 filed on Jul. 25, 2023, the entire contents of which are incorporated herein by reference.

### TECHNICAL FIELD

The present invention relates to a nitride semiconductor light-emitting element.

### BACKGROUND OF THE INVENTION

Patent Literature 1 discloses a nitride semiconductor light-emitting element in which V-pits, which are a type of crystal defect, are formed in a light-emitting layer. Patent Literature 1 also describes that since the V-pits are formed in the light-emitting layer, occurrence of non-luminescent recombination is suppressed and luminous efficiency is thereby improved.
Citation List Patent Literature 1: JP2015-050247A

### SUMMARY OF THE INVENTION

In case of the nitride semiconductor light-emitting element described in Patent Literature 1, however, there is room for improvement in terms of suppressing a decrease in light output over time and thereby extending service life.

The invention was made in view of such circumstances and it is an object of the invention to provide a nitride semiconductor light-emitting element that can achieve an extended service life.

To achieve the object described above, the invention provides a nitride semiconductor light-emitting element, comprising:
an n-type semiconductor layer;
an active layer being formed on the n-type semiconductor layer and emitting ultraviolet light;
an electron blocking layer formed on the active layer; and
a p-type semiconductor layer formed on the electron blocking layer,
wherein a plurality of pits are formed at least in the active layer, and
wherein a ratio R=D2/D1, which is a ratio of a second density D2 to a first density D1, is less than 30%, where the first density D1 is a density of the pits on an upper surface of the active layer and the second density D2 is a density of the pits on an upper surface of the electron blocking layer.

### Advantageous Effects of the Invention

According to the invention, it is possible to provide a nitride semiconductor light-emitting element that can achieve an extended service life.

### BRIEF DESCRIPTION OF DRAWINGS

FIG. 1 is a schematic diagram illustrating a configuration of a nitride semiconductor light-emitting element in an embodiment.

FIG. 2 is a schematic diagram illustrating an example of a pit formed in the nitride semiconductor light-emitting element in the embodiment.

FIG. 3 is a graph showing silicon and magnesium concentration distributions for each of the nitride semiconductor light-emitting elements in Example and Comparative Example.

FIG. 4 is an example AFM image showing an upper surface of an active layer in Example and Comparative Example.

FIG. 5 is an example AFM image showing an upper surface of an electron blocking layer in Example.

FIG. 6 is an example AFM image showing an upper surface of an electron blocking layer in Comparative Example.

FIG. 7 is a schematic diagram illustrating an example of the pit formed in the nitride semiconductor light-emitting element in Comparative Example.

FIG. 8 is a diagram illustrating a relationship between current supply time and light output for Examples B1, B2 and Comparison Examples B1, B2.

FIG. 9 is a diagram illustrating a relationship between current supply time and light output retention rate for Examples B1, B2 and Comparison Examples B1, B2.

### DETAILED DESCRIPTION OF THE INVENTION

### Embodiment

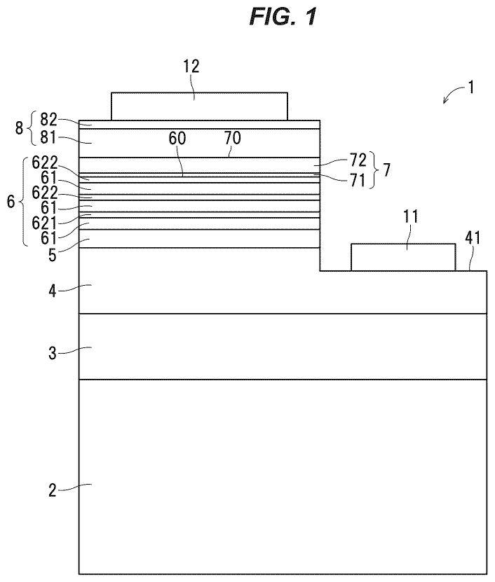

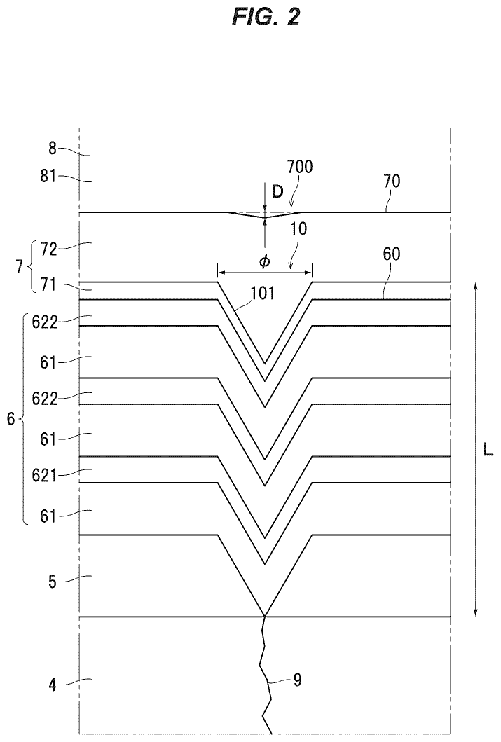

An embodiment of the invention will be described in reference to FIGS. 1 and 2. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1. In FIG. 1, the scale ratio of each semiconductor layer of the nitride semiconductor light-emitting element 1 (hereinafter, also simply referred to as the “light-emitting element 1”) in a stacking direction is not necessarily the same as the actual scale ratio. Hereinafter, the direction of stacking each semiconductor layer of the light-emitting element 1 is referred to as the up-and-down direction. In addition, one side in the up-and-down direction, which is a side of a substrate 2 where each semiconductor layer is grown, (e.g., an upper side in FIG. 1) will be referred to as the upper side, and the opposite side (e.g., a lower side in FIG. 1) will be referred to as the lower side. In this regard, the terms “upper” and “lower” are used for descriptive purposes and do not limit the posture of the light-emitting element 1 with respect to the vertical direction when, e.g., the light-emitting element 1 is used.

The light-emitting element 1 constitutes, e.g., a light-emitting diode (LED) or a semiconductor laser (LD: laser diode). In the present embodiment, the light-emitting element 1 constitutes a light-emitting diode that emits light with a wavelength in an ultraviolet region. Particularly, the light-emitting element 1 in the present embodiment emits ultraviolet light at a central wavelength of not less than 240 nm and not more than 365 nm. The light-emitting element 1 can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type semiconductor layer 4, a composition gradient layer 5, an active layer 6, an electron blocking layer 7 and a p-type semiconductor layer 8 in this order on a substrate 2. The light-emitting element 1 also includes an n-side electrode 11 provided on the n-type semiconductor layer 4, and a p-side electrode 12 provided on the p-type semiconductor layer 8.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). In the present embodiment, binary or ternary group III nitride semiconductors expressed by Al_{c}Ga_{1-c}N (0≤c≤1) are used as the semiconductors constituting the light-emitting element 1. These group III elements may be partially substituted with boron (B) or thallium (TI), etc. In addition, nitrogen (N) may be partially substituted with phosphorus (P), arsenic (As), antimony (Sb) or bismuth (Bi), etc.

The substrate 2 is made of a material transparent to light emitted by the active layer 6. The substrate 2 is, e.g., a sapphire (Al₂O₃) substrate. An upper surface of the substrate 2 is a c-plane. This c-plane may have an off-angle. Alternatively, e.g., an aluminum nitride (AlN) substrate or an aluminum gallium nitride (AlGaN) substrate, etc., may be used as the substrate 2.

The buffer layer 3 is formed on the substrate 2. In the present embodiment, the buffer layer 3 is made of aluminum nitride. When the substrate 2 is an aluminum nitride substrate or an aluminum gallium nitride substrate, the buffer layer 3 may not be necessarily included. The buffer layer 3 may also include a layer made of undoped AlₚGa₁₋ₚN (0≤p≤1) that is formed on the layer made of aluminum nitride.

The n-type semiconductor layer 4 is formed on the buffer layer 3. The n-type semiconductor layer 4 is, e.g., an n-type cladding layer made of Al_{q}Ga_{1-q}N (0≤q≤1) doped with an n-type impurity. In the present embodiment, silicon (Si) is used as the n-type impurity. The same applies to the semiconductor layers containing an n-type impurity other than the n-type semiconductor layer 4. Alternatively, germanium (Ge), selenium (Se) or tellurium (Te), etc., may be used as the n-type impurity. The n-type semiconductor layer 4 may be a single layer or may have a multilayer structure.

The composition gradient layer 5 is formed on the n-type semiconductor layer 4. The composition gradient layer 5 is made of AlᵣGa₁₋ᵣN (0≤r≤1). In the composition gradient layer 5, an Al composition ratio at each position in the up-and-down direction is higher at an upper position. The composition gradient layer 5 may have, e.g., a very small region in the up-and-down direction (e.g., a region of not more than 5% of the entire composition gradient layer 5 in the up-and-down direction) in which the Al composition ratio does not increase toward the upper side.

The Al composition ratio of a lower end portion of the composition gradient layer 5 is preferably substantially the same (e.g., a difference within 5%) as an Al composition ratio of an upper portion of the n-type semiconductor layer 4 that is adjacent to the composition gradient layer 5 on the lower side. In addition, the Al composition ratio of an upper end portion of the composition gradient layer 5 is preferably substantially the same (e.g., a difference within 5%) as an Al composition ratio of a lower portion of a barrier layer 61 that is adjacent to the composition gradient layer 5 on the upper side.

The composition gradient layer 5 also serves as a trigger layer from which pits (see the reference sign 10 in FIG. 2) originate. The details of the pits will be described later. The trigger layer is, e.g., a layer containing a high concentration of silicon. A silicon concentration in the trigger layer can be adjusted based on a density of dislocations 9 present in the n-type semiconductor layer 4 and a target density of the pits in the active layer 6. In the present embodiment, the silicon concentration in the trigger layer is not less than 5.0×10¹⁸ atoms/cm³ and not more than 5.0×10¹⁹ atoms/cm³.

The active layer 6 is formed on the composition gradient layer 5 serving as the trigger layer. The active layer 6 in the present embodiment has a multiple quantum well structure which includes plural well layers 621, 622. A band gap of the active layer 6 is adjusted so that ultraviolet light at a central wavelength of not less than 240 nm and not more than 365 nm can be output. When the active layer 6 has a multiple quantum well structure as in the present embodiment, the central wavelength of ultraviolet light emitted by the active layer 6 is preferably not less than 250 nm and not more than 300 nm, more preferably, not less than 260 nm and not more than 290 nm from the viewpoint of improving light output. In the present embodiment, the active layer 6 has three barrier layers 61 and three well layers 621, 622 which are alternately stacked. In the active layer 6, the barrier layer 61 is located at the lower end and the well layer 622 is located at the upper end.

Each barrier layer 61 is made of AlₛGa₁₋ₛN (0<s≤1). An Al composition ratio of each barrier layer 61 is, e.g., not less than 75% and not more than 95%. Each barrier layer 61 has a film thickness of, e.g., not less than 2 nm and not more than 50 nm.

The well layers 621, 622 are made of AlₜGa₁₋ₜN (0<t<1). An Al composition ratio t of each of the well layers 621, 622 is smaller than the Al composition ratio s of the barrier layers 61 (i.e., t<s).

The three well layers 621, 622 are configured such that the lowermost well layer 621, which is the well layer arranged on the lowermost side, has a different configuration from the upper-side well layers 622 which are two well layers other than the lowermost well layer 621. For example, a film thickness of the lowermost well layer 621 is not less than 1 nm greater than a film thickness of each of the two upper-side well layers 622 and the Al composition ratio of the lowermost well layer 621 is not less than 2% greater than the Al composition ratio of each of the two upper-side well layers 622. In the present embodiment, the upper-side well layers 622 have a film thickness of not less than 2 nm and not more than 4 nm and an Al composition ratio of not less than 25% and not more than 45%, and the lowermost well layer 621 has a film thickness of not less than 4 nm and not more than 6 nm and an Al composition ratio of not less than 35% and not more than 55%. A difference between the film thickness of the lowermost well layer 621 and the film thickness of each upper-side well layer 622 can be not less than 2 nm and not more than 4 nm.

By increasing the Al composition ratio of the lowermost well layer 621 to higher than the Al composition ratio of the upper-side well layers 622, crystallinity of the lowermost well layer 621 is improved. This is because the difference in the Al composition ratio between the lowermost well layer 621 and the n-type semiconductor layer 4 is reduced. The improved crystallinity of the lowermost well layer 621 improves crystallinity of each semiconductor layer formed on and above the lowermost well layer 621 in the active layer 6. As a result, carrier mobility in the active layer 6 is improved and light output is improved. Such effects are more pronounced when the lowermost well layer 621 has a larger film thickness, but the film thickness of the lowermost well layer 621 is designed to be not more than a predetermined value from the viewpoint of suppressing an increase in the electrical resistance value of the entire light-emitting element 1.

The lowermost well layer 621 contains silicon. This can also induce formation of the pits in the active layer 6. In the present embodiment, a silicon concentration in the lowermost well layer 621 is not less than 1.0×10¹⁹ atoms/cm³ and not more than 6.0×10¹⁹ atoms/cm³. The upper-side well layers 622 may also contain an n-type impurity such as silicon, and in this case, the lowermost well layer 621 preferably has the highest silicon concentration among the plural well layers 621, 622.

Although the example in which the active layer 6 has a multiple quantum well structure with the three well layers 621, 622 has been described in the present embodiment, it is not limited thereto. The active layer 6 may have a multiple quantum well structure with two or not less than four well layers. Alternatively, the active layer 6 may have a single quantum well structure having only one well layer.

The electron blocking layer 7 is formed on the active layer 6. The electron blocking layer 7 serves to improve efficiency of electron injection into the active layer 6 by suppressing occurrence of the overflow phenomenon in which electrons leak from the active layer 6 to the p-type semiconductor layer 8 side (hereinafter, also referred to as the electron blocking effect). The electron blocking layer 7 has a stacked structure in which a first layer 71 and a second layer 72 are stacked in this order from the lower side.

The first layer 71 is provided on the active layer 6. The first layer 71 is made of, e.g., AlᵤGa₁₋ᵤN (0<u≤1). An Al composition ratio u of the first layer 71 is, e.g., not less than 90% and is made of aluminum nitride in the present embodiment. A film thickness of the first layer 71 is, e.g., not less than 0.5 nm and not more than 5.0 nm.

The second layer 72 is made of, e.g., AlᵥGa₁₋ᵥN (0<v<1). An Al composition ratio v of the second layer 72 is smaller than the Al composition ratio t of the first layer 71 (i.e., v<t) and is, e.g., not less than 70% and not more than 90%. A film thickness of the second layer 72 is larger than the film thickness of the first layer 71 and is, e.g., not less than 15 nm and not more than 100 nm.

When the first layer 71 with a relatively high Al composition ratio has an excessively large film thickness, it causes an excessive increase in the electrical resistance value of the entire light-emitting element 1 since a semiconductor layer with a higher Al composition ratio has a higher electrical resistance value. For this reason, the film thickness of the first layer 71 is preferably small to some extent. On the other hand, if the film thickness of the first layer 71 is reduced, it increases the probability that electrons pass through the first layer 71 from the lower side to the upper side due to the tunnel effect. Therefore, in the light-emitting element 1 of the present embodiment, the second layer 72 is formed on the first layer 71 to suppress passage of electrons through the entire electron blocking layer 7.

Each of the first layer 71 and the second layer 72 is composed of an undoped semiconductor layer or a semiconductor layer doped with a low concentration of an impurity. In the present embodiment, the electron blocking layer 7 is composed of undoped semiconductor layers. As will be described in detail later, a ratio of a density of the pits (see the reference sign 10 in FIG. 2) on an upper surface 70 of the electron blocking layer 7 (i.e., the upper surface 70 of the second layer 72) to a density of the pits on an upper surface 60 of the active layer 6 is preferably less than 30%, and from the viewpoint of reducing the density of the pits on the upper surface 70 of the electron blocking layer 7, it is preferable that the impurity concentration in the electron blocking layer 7 be low, and it is more preferable that the electron blocking layer 7 be an undoped semiconductor layer. The electron blocking layer 7 may be composed of a single layer or may be composed of not less than three layers.

Silicon is included between the electron blocking layer 7 and the p-type semiconductor layer 8. Silicon and magnesium are likely to be attracted to each other, hence, by including silicon between the electron blocking layer 7 and the p-type semiconductor layer 8, magnesium trying to diffuse from the p-type semiconductor layer 8 toward the active layer 6 is blocked by the silicon between the electron blocking layer 7 and the p-type semiconductor layer 8. In addition, hydrogen is likely to bond with magnesium, hence, diffusion of hydrogen from the p-type semiconductor layer 8 into the active layer 6 is also suppressed with the above-mentioned suppression of diffusion of magnesium from the p-type semiconductor layer 8 into the active layer 6. Diffusion of magnesium and hydrogen into the active layer 6 may cause degradation of the active layer 6 and shorten the service life of the light-emitting element 1, but the service life of the light-emitting element 1 can be extended by including silicon between the electron blocking layer 7 and the p-type semiconductor layer 8.

Silicon between the electron blocking layer 7 and the p-type semiconductor layer 8 may be present in at least one of the following states: a solid solution state in the crystal; a cluster state; and a state in which a compound containing silicon is precipitated. The solid solution state of silicon in the crystal is a state in which silicon is doped in aluminum gallium nitride constituting a boundary portion between the electron blocking layer 7 and the p-type semiconductor layer 8, i.e., a state in which silicon is located at lattice positions of aluminum gallium nitride. The cluster state of silicon is a state in which silicon excessively doped in aluminum gallium nitride constituting the boundary portion between the electron blocking layer 7 and the p-type semiconductor layer 8 is present at the lattice positions of aluminum gallium nitride and is also present as aggregates, etc., between the lattice positions. The state in which a compound containing silicon is precipitated is a state in which, e.g., silicon nitride, etc., is formed. In the boundary portion between the electron blocking layer 7 and the p-type semiconductor layer 8, a silicon-containing layer may be formed or silicon-containing portions may be scattered in a plane direction orthogonal to the stacking direction.

The p-type semiconductor layer 8 is formed on the electron blocking layer 7. The p-type semiconductor layer 8 has a lower Al composition ratio than that of the electron blocking layer 7 and is made of Al_{w}Ga_{1-w}N (0≤w≤1) doped with a p-type impurity. Magnesium (Mg) can be used as the p-type impurity, but zinc (Zn), beryllium (Be), calcium (Ca), strontium (Sr), barium (Ba) or carbon (C), etc., may be used other than magnesium. In the present embodiment, the p-type semiconductor layer 8 has a p-type cladding layer 81 and a p-type contact layer 82 in this order from the lower side.

The p-type cladding layer 81 is provided so as to be in contact with the upper surface 70 of the electron blocking layer 7. An Al composition ratio of the p-type cladding layer 81 can be set to lower than an Al composition ratio of a semiconductor layer of the electron blocking layer 7 adjacent to the p-type cladding layer 81 (i.e., lower than the Al composition ratio of the second layer 72), and higher than an Al composition ratio of the p-type contact layer 82. A film thickness of the p-type cladding layer 81 is, e.g., not less than 9 nm and not more than 105 nm.

The p-type contact layer 82 is a layer connected to the p-side electrode 12 (described later) and is doped with a high concentration of a p-type impurity. The p-type contact layer 82 is configured to have a low Al composition ratio (e.g., not more than 10%) to achieve an ohmic contact with the p-side electrode 12, and from such a viewpoint, the p-type contact layer 82 is preferably made of p-type gallium nitride (GaN). Since the p-type contact layer 82 with a low Al composition ratio can absorb ultraviolet light emitted from the active layer 6, a film thickness of the p-type contact layer 82 is preferably not more than 50 nm.

The n-side electrode 11 is formed on an exposed surface 41 of the n-type semiconductor layer 4 which is exposed from the active layer 6 on the upper side. The n-side electrode 11 can be, e.g., a multilayered film formed by sequentially stacking titanium (Ti), aluminum, titanium and gold (Au) on the n-type semiconductor layer 4. When the light-emitting element 1 is flip-chip mounted as described below, the n-side electrode 11 may be composed of a material that can reflect ultraviolet light emitted by the active layer 6.

The p-side electrode 12 is formed on an upper surface of the p-type semiconductor layer 8. The p-side electrode 12 can be, e.g., a multilayered film formed by sequentially stacking nickel (Ni) and gold on the p-type semiconductor layer 8. When the light-emitting element 1 is flip-chip mounted as described below, the p-side electrode 12 may be composed of a material that can reflect ultraviolet light emitted by the active layer 6.

The light-emitting element 1 can be used in a state of being flip-chip mounted on a package substrate (not shown). That is, the light-emitting element 1 is mounted such that a side in the up-and-down direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side (i.e., on the lower side). However, it is not limited thereto and the light-emitting element 1 may be mounted on the package substrate by wire bonding, etc. In addition, although the light-emitting element 1 in the present embodiment is a so-called lateral light-emitting element in which both the n-side electrode 11 and the p-side electrode 12 are provided on the upper side of the light-emitting element 1, the light-emitting element 1 is not limited thereto and may be a vertical light-emitting element. The vertical light-emitting element is a light-emitting element in which the active layer is sandwiched between the n-side electrode and the p-side electrode. In this regard, when the light-emitting element is of the vertical type, the substrate and the buffer layer are preferably removed by laser lift-off, etc.

Next, the pits 10 formed in the light-emitting element 1 in the present embodiment will be described. FIG. 2 is a schematic diagram illustrating an example of the pit 10 formed in the light-emitting element 1 in the present embodiment.

As shown in FIG. 2, the pit 10 is a type of crystal defect that originates from the dislocation 9 propagated from the n-type semiconductor layer 4 side. It is considered that a growth mode of a matrix of the composition gradient layer 5 changes when a silicon source of not less than a predetermined concentration is supplied, during growth of the composition gradient layer 5 as the trigger layer, to locations where the dislocations 9 propagated from the n-type semiconductor layer 4 side are present, and the pits 10 are thereby formed. A portion of an upper surface of the composition gradient layer 5 is recessed and each semiconductor layer of the active layer 6 located thereon is further recessed along the recess on the upper surface of the composition gradient layer 5, and the pit 10 is thereby formed in a multi-layered manner.

The light-emitting element 1 in the present embodiment is formed so that the density of the pits 10 observed on the upper surface 70 of the electron blocking layer 7 is lower than the density of the pits 10 observed on the upper surface 60 of the active layer 6. That is, the light-emitting element 1 in the present embodiment has many pits 10 as shown in FIG. 2, i.e., the pits 10 that are formed from the composition gradient layer 5 serving as the trigger layer to at least the upper surface 60 of the active layer 6 but not to the upper surface 70 of the electron blocking layer 7.

A ratio R=D2/D1, which is a ratio of a second density D2 to a first density D1, is less than 30%, more preferably less than 15%, where the first density D1 is the density of the pits 10 on the upper surface 60 of the active layer 6 and the second density D2 is the density of the pits 10 on the upper surface 70 of the electron blocking layer 7. As will be described in detail later, reducing the ratio R improves the light output retention rate of the light-emitting element 1 and extends its service life. The light output retention rate of the light-emitting element 1 is a ratio of the current light output to the initial light output.

It is known that when the pits 10 are formed in the active layer 6, occurrence of non-luminescent recombination is suppressed and the light output is improved (see, e.g., JP2019-054247 A). For this reason, it is preferable that the pits 10 be formed in the active layer 6. From the viewpoint of improving the light output, the density of the pits 10 observed on the upper surface 60 of the active layer 6 is preferably not less than 1.0×10⁹ pits/cm² and not more than 5.0×10⁹ pits/cm². The density of the pits 10 on the upper surface 60 of the active layer 6 can be controlled, e.g., by adjusting the density of dislocations present in the n-type semiconductor layer 4 and the silicon concentration in the composition gradient layer 5 serving as the trigger layer, etc.

There is an advantage in the formation of the pits 10 in the active layer 6 as mentioned above, but if there are many pits 10 which are formed up to the upper surface 70 of the electronic blocking layer 7, the light output of the light-emitting element 1 is likely to decrease over time and the service life of the light-emitting element 1 is shortened. This is presumably because when the pits 10 are formed up to the upper surface 70 of the electron blocking layer 7, magnesium, which is contained in the p-type semiconductor layer 8, and hydrogen, which easily bonds to magnesium, are likely to diffuse into the active layer 6 through the pits 10.

Therefore, by reducing the ratio R to as low as less than 30% as described above, the advantage in the formation of the pits 10 in the active layer 6, which is improvement in the light output, and the advantage in having few pits 10 formed up to the upper surface 70 of the electron blocking layer 7, which is longer service life, are obtained. From this point of view, the ratio R is preferably less than 15%.

The reduction of the second density D2 can be achieved, e.g., by reducing an impurity concentration in the electron blocking layer 7. Impurities such as magnesium and silicon tend to gather around the pits 10. Therefore, when the electron blocking layer 7 is doped with an impurity such as magnesium, it is presumed that the impurity in the electron blocking layer 7 is attracted to the pits 10, diagonal growth along the pits 10 in the areas where the pits 10 exist is promoted during deposition of the electron blocking layer 7, and the pits 10 formed in the active layer 6 are transferred to the electron blocking layer 7.

Therefore, from the viewpoint of reducing the ratio R, it is preferable that the impurity concentration in the electron blocking layer 7 be low, and it is more preferable that the electron blocking layer 7 be undoped. From the viewpoint of lowering the impurity concentration in the electron blocking layer 7 and thereby reducing the ratio R, it is preferable that the Al composition ratio of the electron blocking layer 7 be high. In this regard, the second density D2 may be reduced by a method other than adjustment of the impurity concentration in the electron blocking layer 7. For example, increasing the film thickness of the entire electron blocking layer 7 is considered to reduce the second density D2.

FIG. 2 shows an example in which the pit 10 is formed up to the upper surface of the first layer 71 of the electron blocking layer 7 but is buried in the second layer 72 and is not formed up to the upper surface 70 of the second layer 72. In the present embodiment, it is presumed that the first layer 71 cannot completely fill the pits 10 since the film thickness of the first layer 71 is as very small as not less than 0.5 nm and not more than 5.0 nm as mentioned above, but the second layer 72 has a low impurity concentration and a film thickness which is more than the film thickness of each semiconductor layer of the active layer 6, hence, the pits 10 are easily buried. Therefore, to reduce the ratio R, it is preferable that the electron blocking layer 7 include at least one semiconductor layer which is thicker than each semiconductor layer of the active layer 6 and has a low impurity concentration (preferably undoped). In addition, the film thickness of the entire electron blocking layer 7 is preferably not less than twice the film thickness of the thickest semiconductor layer among the semiconductor layers constituting the active layer 6.

In the example in FIG. 2, a minute depression 700 which appears on the upper surface 70 of the electron blocking layer 7 at the portion located above the pit 10 is also schematically shown. The minute depression 700 may appear on the upper surface 70 of the second layer 72 as a trace of burying the pit 10 in the second layer 72 of the electronic blocking layer 7. The minute depression 700 is a depression which is minute with a depth D of less than 1 nm, and such a depression is not regarded as a pit. In other words, the second density D2 is a density of depressions with the depth D of not less than 1 nm on the upper surface 70 of the electron blocking layer 7. On the upper surface 70 of the electron blocking layer 7, a density of relatively large pits 10 with the depth D of not less than 2 nm is preferably not more than 1.0×10⁸ pits/cm².

A recessed surface 101 located at the uppermost position of the pit 10 is recessed so that a cross section parallel to the up-and-down direction has a substantially V-shape. The recessed surface 101 as a whole has a substantially cone or pyramid shape (e.g., a substantially cone shape, a substantially polygonal pyramid shape, an elliptic cone shape), or a substantially truncated cone or pyramid shape, with the region inside the recessed surface 101 becoming smaller toward the lower side. The pit 10 with the recessed surface 101 having a V-shaped cross section as described above is called a V-pit. The shape of the recessed surface 101 may be a circular column shape or a polygonal column shape, other than that having a V-shaped cross section. A diameter Φ of the uppermost edge of the recessed surface 101 of the pit 10 is not more than 100 nm, more specifically, not less than 20 nm and not more than 60 nm. When the recessed surface 101 of the pit 10 has a shape other than a cone, such as a polygonal pyramid, the diameter @ can be a diameter of a circle obtained when the uppermost edge of the recessed surface 101 is approximated by a circumscribed circle, etc. The total length L of the pit 10 in the up-and-down direction is, e.g., not less than 1 nm and not more than 60 nm.

### Method for Manufacturing the Nitride Semiconductor Light-Emitting Element 1

Next, an example of a method for manufacturing the light-emitting element 1 in the present embodiment will be described.

In the present embodiment, the buffer layer 3, the n-type semiconductor layer 4, the composition gradient layer 5, the active layer 6, the electron blocking layer 7 and the p-type semiconductor layer 8 are epitaxially grown on the disc-shaped substrate 2 in this order by the Metal Organic Chemical Vapor Deposition (MOCVD) method. That is, in the present embodiment, the disc-shaped substrate 2 is placed in a chamber and each semiconductor layer is formed on the substrate 2 by introducing source gases of each semiconductor layer to be formed on the substrate 2 into the chamber. As the source gases to epitaxially grow each semiconductor layer, it is possible to use trimethylaluminum (TMA) as an aluminum source, trimethylgallium (TMG) as a gallium source, ammonia (NH₃) as a nitrogen source, tetramethylsilane (TMSi) as a silicon source, and biscyclopentadienylmagnesium (Cp₂Mg) as a magnesium source.

In forming the composition gradient layer 5, an amount of the silicon source supplied to the chamber is adjusted based on the density of the dislocations 9 present in the n-type cladding layer 4 and the target density of the pits 10 in the active layer 6, etc.

The MOCVD method is sometimes called the Metal Organic Vapor Phase Epitaxy (MOVPE) method. To epitaxially grow each semiconductor layer on the substrate 2, it is also possible to use another epitaxial growth method such as the Molecular Beam Epitaxy (MBE) method or the Hydride Vapor Phase Epitaxy (HVPE) method, etc.

After forming each semiconductor layer on the disc-shaped substrate 2, a mask is formed on a portion of the p-type semiconductor layer 8, i.e., a part other than the portion to be the exposed surface 41 of the n-type semiconductor layer 4. Then, the region in which the mask is not formed is removed by etching from the upper surface of the p-type semiconductor layer 8 to the middle of the n-type semiconductor layer 4 in the up-and-down direction. The exposed surface 41 exposed upward is thereby formed on the n-type semiconductor layer 4. After forming the exposed surface 41, the mask is removed.

Subsequently, the n-side electrode 11 is formed on the exposed surface 41 of the n-type semiconductor layer 4 and the p-side electrode 12 is formed on the p-type semiconductor layer 8. The n-side electrode 11 and the p-side electrode 12 may be formed by, e.g., a well-known method such as the electron beam evaporation method or the sputtering method. The object completed through the above process is cut into pieces with a desired dimension. Plural light-emitting elements 1 as shown in FIG. 1 are thereby obtained from one wafer.

### Functions and Effects of the Embodiment

The ratio R=D2/D1, which is the ratio of the second density D2 to the first density D1, is less than 30%, where the first density D1 is the density of the pits 10 on the upper surface 60 of the active layer 6 and the second density D2 is the density of the pits 10 on the upper surface 70 of the electron blocking layer 7. Therefore, the light output retention rate of the light-emitting element 1 is improved and the service life of the light-emitting element 1 is extended.

In addition, the electron blocking layer 7 is composed of undoped semiconductor layers. This makes it easier to reduce the second density D2 as described above.

In addition, the ratio R further satisfies less than 15%. Therefore, the service life of the light-emitting element 1 is further extended.

In addition, on the upper surface 70 of the electron blocking layer 7, the density of the pits 10 with the depth of not less than 2 nm is not more than 1.0×10⁸ pits/cm². Since the number of deep pits 10 on the upper surface 70 of the electron blocking layer 7 is small, the diffusion of magnesium, which is contained in the p-type semiconductor layer 8, and hydrogen, which easily bonds to magnesium, into the active layer 6 through the pits 10 is suppressed, and the service life of the light-emitting element 1 is thereby further extended.

In addition, the film thickness of the p-type contact layer 82 made of p-type GaN is not more than 50 nm. In such a case, the service life of the light-emitting element 1 tends to be short, but the service life of the light-emitting element 1 can be extended by setting the ratio R to less than 30% as described above.

In addition, the film thickness of the electron blocking layer 7 is greater than the film thickness of each semiconductor layer of the active layer 6. This increases the probability that the pits 10 are buried when depositing the electron blocking layer 7, and the second density D2 is thereby reduced.

As described above, according to the present embodiment, it is possible to provide a nitride semiconductor light-emitting element that can achieve an extended service life.

### Experiment Example

This Experimental Example is an example in which the relationship between the ratio R and the light output retention rate was confirmed. In Experimental Example and subsequent sections, the names of components that are the same as those used in the previously described embodiment indicate the same components as those in the previously described embodiment, unless otherwise specified.

In this Experimental Example, first, wafers according to Examples A1 to A6 and wafers according to Comparative Examples A1 to A6 were made. In Examples A1 to A6, the wafers have the same stacking structure as the light-emitting element described in the embodiment, and the first layer 71 and the second layer 72 of the electron blocking layer 7 are both undoped. In Comparative Examples A1 to A6, the wafers have the same structure as Examples A1 to A6, except that the second layer 72 is doped with magnesium. In consideration of manufacturing variations, plural elements were made as Examples A1 to A6 by the same manufacturing method. Similarly, in consideration of manufacturing variations, plural elements were made as Comparative Examples A1 to A6 by the same manufacturing method. Table 1 shows the configurations of Examples A1 to A6 and Comparative Examples A1 to A6.

TABLE 1

| | | | | Al | Si | Mg |
|---|---|---|---|---|---|---|
| | | Film | | composition ratio | concentration | concentration |
| Structure | | thickness | | [%] | [atoms/cm³] | [atoms/cm³] |
| Substrate | | 430 ± 25 | [um] | — | BG | BG |
| Buffer layer | | 2000 ± 200 | [nm] | 100 | BG | BG |
| n-type semiconductor layer | | 2000 ± 200 | [nm] | 55 ± 10 | (1.50 ± 1.00)E+19 | BG |
| Composition gradient layer | | 15 ± 5 | [nm] | 55→85 | * BG - Peak concentration in | BG |
| | | | | | Lowermost well layer | |
| Active | Barrier layer | 7 ± 5 | [nm] | 85 ± 10 | * BG - Peak concentration in | BG |
| layer | | | | | Lowermost well layer | |
| (3QW) | Well layer | 5 ± 1 | [nm] | 45 ± 10 | (3.50 ± 2.50)E+19 | BG |
| | (Lowermost | | | | (Peak concentration) | |
| | well layer) | | | | | |
| | Barrier layer | 7 ± 5 | [nm] | 85 ± 10 | BG - Peak concentration in | BG |
| | | | | | Lowermost well layer | |
| | Well layer | 3 ± 1 | [nm] | 35 ± 10 | BG-1.00E+19 | BG |
| | (Upper-side | | | | | |
| | well layer) | | | | | |
| | Barrier layer | 7 ± 5 | [nm] | 85 ± 10 | BG-1.00E+19 | BG |
| | Well layer | 3 ± 1 | [nm] | 35 ± 10 | BG-1.00E+18 | BG |
| | (Upper-side | | | | | |
| | well layer) | | | | | |
| Electron | First layer | 2 ± 1 | [nm] | 95 ± 5 | BG | Example: |
| blocking | | | | | | Comparative Example: |
| layer | | | | | | * BG-1.00E+19 |
| | Second layer | 20 ± 10 | [nm] | 80 ± 10 | BG | Example: BG |
| | | | | | | Comparative Example: |
| | | | | | | * BG-1.00E+18-1.00E+20 |
| P-type | p-type cladding | 30 ± 20 | [nm] | 60 ± 5 | BG-1.00E+20 | 1.00E+18-1.00E+20 |
| semiconductor | layer | | | | | |
| layer | p-type contact | 22 ± 20 | [nm] | 0 | BG | 5.00E+18-5.00E+20 |
| | layer | | | | | |

The film thickness of each semiconductor layer shown in Table 1 was measured by a transmission electron microscope. The A1 composition ratio of each semiconductor layer shown in Table 1 is a value estimated from secondary ion intensity of A1 measured by Secondary Ion Mass Spectrometry (SIMS). The figures in the column for “Composition gradient layer” in Table 1 show that the A1 composition ratio of the composition gradient layer 5 along the up-and-down direction changes from 55% to 85% from the lower end to the upper end.

The “Si concentration” and the “Mg concentration” shown in Table 1 are the silicon concentration and the magnesium concentration obtained using secondary ion mass spectrometry. The silicon concentration in the lowermost well layer 621 in Table 1 indicates the peak of the silicon concentration in the lowermost well layer 621 along the up-and-down direction. In Table 1, the “*” mark in the columns for “Si concentration” and “Mg concentration” means that the film thickness of the semiconductor layer is small and it is difficult to accurately measure the silicon concentration and the magnesium concentration. In addition, in Table 1, “BG” in the columns for “Si concentration” and “Mg concentration” means the background level. The background level is the concentration of silicon or magnesium that would be detected when not doped with silicon or magnesium.

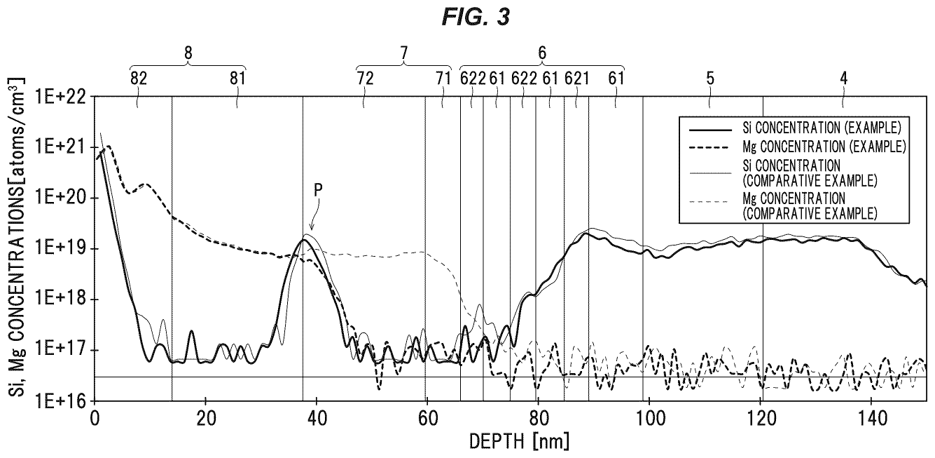

FIG. 3 is a graph showing the silicon and magnesium concentration distributions in the up-and-down direction (hereinafter, also simply referred to as the “silicon concentration distribution” and the “magnesium concentration distribution”) obtained by secondary ion mass spectrometry for each of the light-emitting elements in Examples and Comparative Examples. The depth on the horizontal axis in FIG. 3 represents a depth in the up-and-down direction from the upper surface of the p-type semiconductor layer 8. In FIG. 3, the measurement result of the silicon concentration distribution in Example is represented by a thick solid line, the measurement result of the magnesium concentration distribution in Example is represented by a thick dashed line, the measurement result of the silicon concentration distribution in Comparison Example is represented by a thin solid line, and the measurement result of the magnesium concentration distribution in Comparison Example is represented by a thin dashed line. In addition, in FIG. 3, the depth range of each semiconductor layer is marked with the reference sign of each semiconductor layer used in the embodiment.

First, it can be seen from FIG. 3 that both the first layer 71 and the second layer 72 of the electron blocking layer 7 in Example are undoped. Here, when looking at the magnesium concentration distribution obtained using secondary ion mass spectrometry, even though the electron blocking layer 7 is undoped (i.e., even though the magnesium source is not supplied during the deposition of the electron blocking layer 7), it looks as if magnesium is contained in an end portion of the electron blocking layer 7 on the p-type semiconductor layer 8 side in case that the semiconductor layer adjacent to the electron blocking layer 7 on the upper side is the p-type semiconductor layer 8 containing magnesium, but this is a problem with SIMS measurement. Therefore, when magnesium is contained in the adjoining position of the electron blocking layer 7, it can be said that the electron blocking layer 7 does not contain magnesium if the magnesium concentration in the region of the electron blocking layer 7 other than the region on the adjoining position side (e.g., within a 10 nm range from such a location) is at the background level in the magnesium concentration distribution obtained by secondary ion mass spectrometry. Therefore, in Table 1, the Mg concentration in the second layer 72 in Example is indicated as background.

It can also be seen from FIG. 3 that magnesium is contained in the second layer 72 of the electron blocking layer 7 in Comparative Example. It can be further seen from FIG. 3 that magnesium in the second layer 72 is diffused to the active layer 6 in Comparative Example.

It can also be seen from FIG. 3 that silicon is contained between the electron blocking layer 7 and the p-type semiconductor layer 8. When silicon is contained between the electron blocking layer 7 and the p-type semiconductor layer 8, a peak P of the silicon concentration appears between the electron blocking layer 7 and the p-type semiconductor layer 8 in the silicon concentration distribution. It is preferable that the value of the peak P satisfy not less than 1.0×10¹⁸ atoms/cm³ and not more than 1.0×10²⁰ atoms/cm³. By setting to not less than 1.0×10¹⁸ atoms/cm³, it is easy to suppress diffusion of magnesium from the p-type semiconductor layer 8 side to the active layer 6. Meanwhile, by setting to not more than 1.0×10²⁰ atoms/cm³, it is possible to suppress a decrease in crystallinity of the electron blocking layer 7 and the p-type semiconductor layer 8 which are adjacent to the position of the silicon on both sides. Furthermore, in the silicon concentration distribution in the stacking direction of the light-emitting element 1, the value of the peak P more preferably satisfies not less than 3.0×10¹⁸ atoms/cm³ and not more than 5.0×10¹⁹ atoms/cm³.

Here, when looking at the silicon concentration distribution obtained using secondary ion mass spectrometry, even though the electron blocking layer 7 is undoped (i.e., even though the silicon source is not supplied during the deposition of the electron blocking layer 7), a tail portion, etc., of the peak P appears at the end portion of the electron blocking layer 7 on the p-type semiconductor layer 8 side and it looks as if silicon is contained in the end portion of the electron blocking layer 7 on the p-type semiconductor layer 8 side, but this is a problem with SIMS measurement. Therefore, when silicon is contained in the adjoining position of the electron blocking layer 7, it can be said that the electron blocking layer 7 does not contain silicon if the silicon concentration in the region of the electron blocking layer 7 other than the region on the adjoining position side (e.g., within a 10 nm range from such a location) is at the background level in the silicon concentration distribution obtained by secondary ion mass spectrometry.

Next, for each of Examples A1 to A6 and Comparative Examples A1 to A6, the first density D1, which is the density of the pits 10 on the upper surface 60 of the active layer 6, and the second density D2, which is the density of the pits 10 on the upper surface 70 of the electron blocking layer 7, were obtained and the ratio R=D2/D1 was calculated.

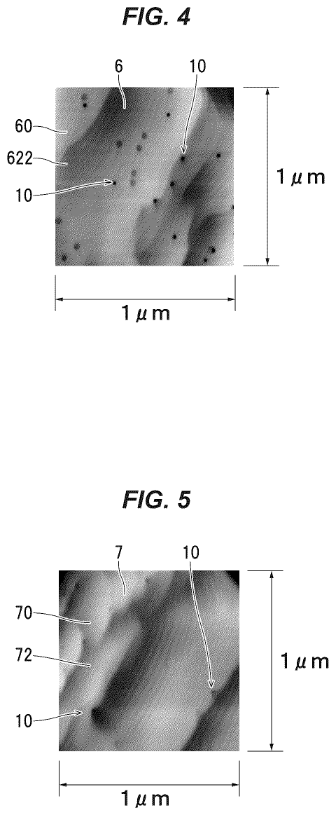

The first density D1 was obtained as follow: first, each of Examples A1-A6 and Comparative Examples A1-A6, which was grown up to the active layer 6, was taken out of the chamber, the upper surface 60 of the active layer 6 was photographed by an atomic force microscope, and the number of the pits 10 in the captured AFM image was counted. FIG. 4 shows an example of the AFM image of the upper surface 60 of the active layer 6. When a 1 μm-square range of the upper surface 60 of the active layer 6 is photographed by an atomic force microscope as shown in FIG. 4 and if n pits 10 are observed in the captured image, the first density D1 of the pits 10 observed in the captured image is calculated to be n [pits/μm²]=n×10⁸ [pits/cm²]. Regarding the first density D1, there was no significant difference between Examples and Comparative Examples as shown in Table 2 described later. In other words, in each of Examples and Comparative Examples, the state of the upper surface 60 of the active layer 6 is similar to the state shown in FIG. 4.

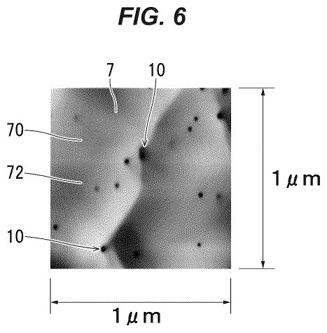

The second density D2 was obtained as follow: using different wafers, deposition was performed up to the electron blocking layer 7 under the same deposition conditions as those used for the wafers that are formed up to active layer 6 to measure the first density D1, the upper surface 70 of the electron blocking layer 7 was photographed by an atomic force microscope, and the number of the pits 10 in the captured image was counted. In each of Examples A1 to A6, the deposition of the wafer up to the active layer 6 to measure the first density D1 and the deposition of the wafer up to the electron blocking layer 7 to measure the second density D2 were performed in short intervals so that the deposition could be said to have been performed substantially simultaneously (i.e., so that the deposition conditions were the same). The same applies to each of Comparative Examples A1 to A6. FIG. 5 is an example AFM image showing the upper surface 70 of the electron blocking layer 7 in Example, and FIG. 6 is an example AFM image showing the upper surface 70 of the electron blocking layer 7 in Comparative Example. Table 2 shows the first density D1, the second density D2 and the ratio R for Examples A1 to A6 and Comparative Examples A1 to A6.

TABLE 2

| | First density D1 | Second density D2 | Ratio R = D2/D1 |
|---|---|---|---|
| | [10⁸ pits/cm²] | [10⁸ pits/cm²] | [%] |
| Example A1 | 21 | 4 | 19.0 |
| Example A2 | 25 | 3 | 12.0 |
| Example A3 | 29 | 4 | 13.8 |
| Example A4 | 33 | 8 | 24.2 |
| Example A5 | 28 | 6 | 21.4 |
| Example A6 | 26 | 7 | 26.9 |
| Comparative | 21 | 13 | 61.9 |
| Example A1 | | | |
| Comparative | 26 | 11 | 42.3 |
| Example A2 | | | |
| Comparative | 29 | 12 | 41.4 |
| Example A3 | | | |
| Comparative | 32 | 17 | 53.1 |
| Example A4 | | | |
| Comparative | 30 | 11 | 36.7 |
| Example A5 | | | |
| Comparative | 26 | 12 | 46.2 |
| Example A6 | | | |

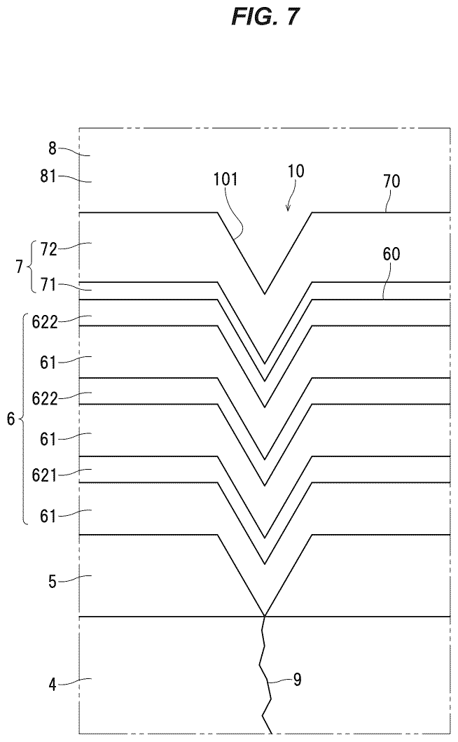

It can be seen from Table 2 and FIGS. 4 to 6 that there is no significant difference in the first density D1 between Examples and Comparative Examples, but the second density D2 is lower in Examples than Comparative Examples. Then, it can be seen from Table 2 that the ratio R of Examples A1 to A6, in which the electron blocking layer 7 is undoped, is less than 30%, and the ratio R of Comparative Examples A1 to A6, in which the second layer 72 of the electron blocking layer 7 is doped with magnesium, is more than 30%. That is, in Examples A1 to A6, there are relatively many pits 10 which are formed at least up to the upper surface 60 of the active layer 6 but buried before reaching the upper surface 70 of the electron blocking layer 7 as shown in FIG. 2. On the other hand, in Comparative Examples A1 to A6, there are relatively many pits 10 which are formed up to the upper surface 70 of the electron blocking layer 7 as shown in the schematic diagram of FIG. 7.

Here, the wafers in Examples A1 to A6 and Comparative Examples A1 to A6 were taken out of the chamber after growing the active layer 6 as well as after regrowing the electron blocking layer 7 to count the first density D1 and the second density D2, but this action may affect the service life of the finished light-emitting element. Therefore, separately from Examples A1 to A6 and Comparative Examples A1 to A, light-emitting elements in Examples B1, B2 and Comparative Examples B1, B2 were made using wafers that were deposited without being taken out of the chamber during the deposition, and transition of light output was observed using these wafers.

Examples B1 and B2 are light-emitting elements made using wafers obtained under the same conditions as Examples A1 to A6, and Comparative Examples B1 and B2 are light-emitting elements made using wafers obtained under the same conditions as Comparative Examples A1 to A6. Since Examples B1 and B2 were made under the same conditions as Examples A1 to A6, the ratio R is expected to be similar to that of Examples A1 to A6, i.e., less than 30%. Likewise, since Comparative Examples B1 and B2 were made under the same conditions as Comparative Examples A1 to A6, the ratio R is expected to be similar to that of Comparative Examples A1 to A6, i.e., not less than 30%.

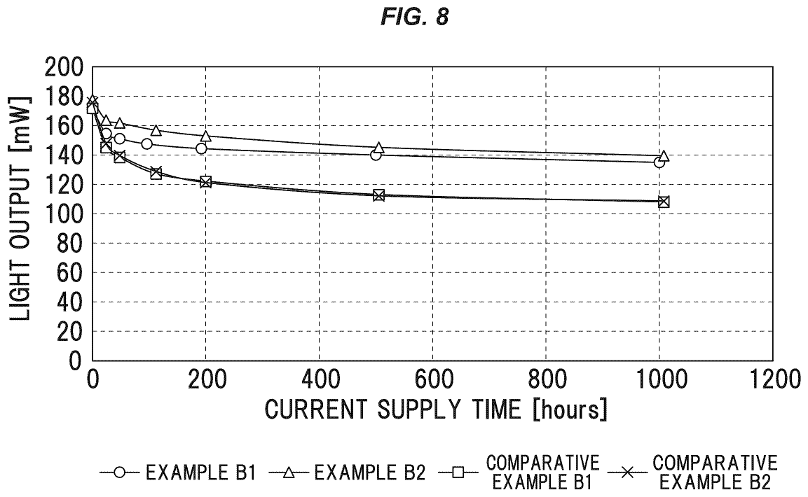

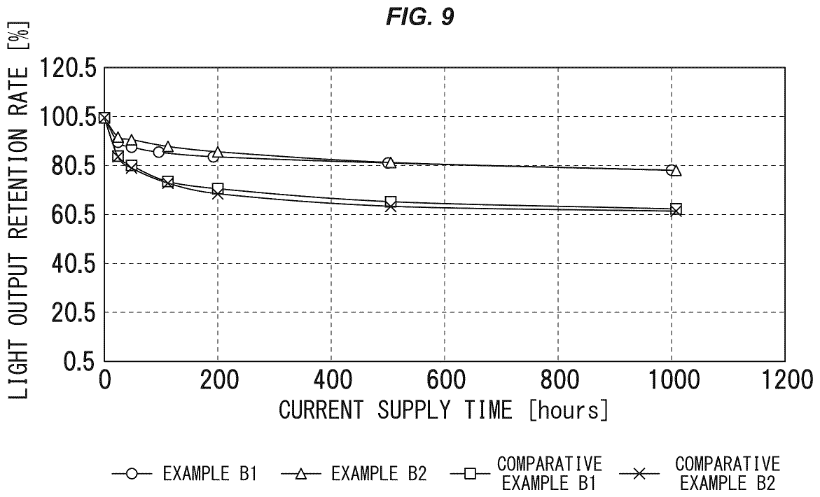

A current of 500 mA was continuously passed through each of Examples B1 and B2 and Comparative Examples B1 and B2 for 1000 hours to cause light emission, and transition of the light output was evaluated. The results of the transition of the light output for Examples B1 and B2 and Comparative Examples B1 and B2 are shown in FIGS. 8 and 9. FIG. 8 is a diagram illustrating a relationship between the current supply time and the light output for Examples B1, B2 and Comparison Examples B1, B2. FIG. 9 is a diagram showing the light output of FIG. 8 when converted into the light output retention rate.

As can be seen from FIGS. 8 and 9, Examples B1 and B2 with the ratio R of less than 30% show a lower rate of decrease in light output than Comparison Examples B1 and B2 with the ratio R of more than 30% and can achieve a longer service life.

### Summary of the Embodiment

Technical ideas understood from the embodiment will be described below citing the reference signs, etc., used for the embodiment. However, each reference sign, etc., described below is not intended to limit the constituent elements in the claims to the members, etc., specifically described in the embodiment.

The first feature of the invention is a nitride semiconductor light-emitting element 1 including an n-type semiconductor layer 4; an active layer 6 being formed on the n-type semiconductor layer 4 and emitting ultraviolet light; an electron blocking layer 7 formed on the active layer 6; and a p-type semiconductor layer 8 formed on the electron blocking layer 7, wherein a plurality of pits 10 are formed at least in the active layer 6, and

wherein a ratio R=D2/D1, which is a ratio of a second density D2 to a first density D1, is less than 30%, where the first density D1 is a density of the pits 10 on an upper surface 60 of the active layer 6 and the second density D2 is a density of the pits 10 on an upper surface 70 of the electron blocking layer 7.

This improves the light output retention rate of the nitride semiconductor light-emitting element 1 and extends the service life of the nitride semiconductor light-emitting element 1.

The second feature of the invention is that, in the first feature, the electron blocking layer 7 comprises an undoped semiconductor layer

This makes it easier to reduce the second density D2.

The third feature of the invention is that, in the first or second feature, the ratio R further satisfies less than 15%.

This further extends the service life of the nitride semiconductor light-emitting element 1.

The fourth feature of the invention is that, in the any one of the first to third features, a density of the pits 10 with a depth of not less than 2 nm on the upper surface 70 of the electron blocking layer 7 is not more than 1.0×10¹⁸ pits/cm².

This further extends the service life of the nitride semiconductor light-emitting element 1.

The fifth feature of the invention is that, in the any one of the first to fourth features, the p-type semiconductor layer 8 comprises a p-type contact layer 82 comprising p-type GaN, and wherein a film thickness of the p-type semiconductor layer 8 is not more than 50 nm.

When the film thickness of the p-type contact layer 82 with a low A1 composition ratio is small, the service life of the nitride semiconductor light-emitting element 1 tends to be short unless special measures are taken. However, even when having such a configuration, the service life of the nitride semiconductor light-emitting element 1 can be extended by setting the ratio R to less than 30% as described above.

The sixth feature of the invention is that, in the any one of the first to fifth features, a film thickness of the electron blocking layer 7 is larger than a film thickness of each semiconductor layer of the active layer 6.

This makes it easier to reduce the second density D2.

### Additional Note

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

1. A nitride semiconductor light-emitting element, comprising:
an n-type semiconductor layer,
an active layer being formed on the n-type semiconductor layer and emitting ultraviolet light;
an electron blocking layer formed on the active layer; and
a p-type semiconductor layer formed on the electron blocking layer,
wherein a plurality of pits are formed at least in the active layer, and
wherein a ratio R=D2/D1, which is a ratio of a second density D2 to a first density D1, is less than 30%, where the first density D1 is a density of the pits on an upper surface of the active layer and the second density D2 is a density of the pits on an upper surface of the electron blocking layer.

2. The nitride semiconductor light-emitting element according to claim 1, wherein the electron blocking layer comprises an undoped semiconductor layer.

3. The nitride semiconductor light-emitting element according to claim 1, wherein the ratio R further satisfies less than 15%.

4. The nitride semiconductor light-emitting element according to claim 1, wherein a density of the pits with a depth of not less than 2 nm on the upper surface of the electron blocking layer is not more than 1.0×10¹⁸ pits/cm².

5. The nitride semiconductor light-emitting element according to claim 1, wherein the p-type semiconductor layer comprises a p-type contact layer comprising p-type GaN, and wherein a film thickness of the p-type semiconductor layer is not more than 50 nm.

6. The nitride semiconductor light-emitting element according to claim 1, wherein a film thickness of the electron blocking layer is larger than a film thickness of each semiconductor layer of the active layer.
